(19) United States
(12) Patent Application Publication
(10) Pub. No.: US 2016/0027966 A1
(43) Pub. Date: Jan. 28, 2016

(54) Porous Quantum Dot Carriers

(71) Applicant: NANOSYS, Inc., Milpitas, CA (US)

(72) Inventors: Robert S. Dubrow, Milpitas, CA (US); Paul Furuta, Milpitas, CA (US)

(21) Appl. No.: 14/799,308

(22) Filed: Jul. 14, 2015

Related U.S. Application Data
(60) Provisional application No. 62/029,150, filed on Jul. 25, 2014.

(51) Int. Cl. H01L 33/48; H01L 33/06; H01L 33/00; H01L 33/52

(52) U.S. Cl. CPC H01L 33/483; H01L 33/52; H01L 33/06; H01L 33/005

(57) ABSTRACT

Embodiments of a quantum dot carrier, a method of making a quantum dot carrier, and a quantum dot enhancement film are described. The quantum dot carrier includes a porous material, a plurality of quantum dots and a dispersing material for dispersing the quantum dots within the porous material. The porous material includes a plurality of pores while the quantum dots are disposed within the plurality of pores.

### CROSS REFERENCE TO RELATED APPLICATIONS

This application claims the benefit of U.S. Provisional Application No. 62/029,150, filed on Jul. 25, 2014, the disclosure of which is incorporated by reference herein in its entirety.

### FIELD

The present application relates to quantum dot emission technology, and to protective carriers for the quantum dots.

### BACKGROUND

Semiconductor nanocrystallites (quantum dots) whose radii are smaller than the bulk exciton Bohr radius constitute a class of materials intermediate between molecular and bulk forms of matter. Quantum confinement of both the electron and hole in all three dimensions leads to an increase in the effective band gap of the material with decreasing crystallite size. Consequently, both the optical absorption and emission of quantum dots shift to the blue (higher energies) as the size of the dots gets smaller.

Currently available light-emitting diodes (LEDs) and related devices that incorporate quantum dots use quantum dots that have been grown epitaxially on a semiconductor layer. This fabrication technique is most suitable for the production of infrared light-emitting devices, but is not ideal for devices using higher-energy colors. Further, the processing costs of epitaxial growth by currently available methods (e.g., molecular beam epitaxy and chemical vapor deposition) are quite high. Colloidal production of quantum dots is a much more inexpensive process, but quantum dots produced by this method must be protected from environmental factors that would degrade their optical performance. The protective material must maintain a favorable environment for the quantum dots while minimizing interference with their quantum efficiency.

### SUMMARY

Embodiments of the present application relate to a quantum dot carrier, its use in an enhancement film, and a method of making the quantum dot carrier. The embodiments of the present application provide advantages over the traditional techniques for protecting quantum dots.

According to an embodiment, a quantum dot carrier includes a porous material, a plurality of quantum dots, and a material for dispersing the quantum dots within the porous material. The porous material includes a plurality of pores in which the quantum dots are disposed.

According to an embodiment, a quantum dot enhancement film includes a first layer, a second layer, and an adhesive material. The adhesive material is disposed between the first layer and the second layer and includes a plurality of quantum dot carriers. Each of the quantum dot carriers includes a porous material, a plurality of quantum dots, and a material for dispersing the quantum dots within the porous material. The porous material includes a plurality of pores in which the quantum dots are disposed.

According to an embodiment, a method includes disposing a plurality of quantum dots within a porous material and dispersing the quantum dots within the porous material using a material disposed along with the quantum dots.

### BRIEF DESCRIPTION OF THE DRAWINGS/FIGURES

The accompanying drawings, which are incorporated herein and form part of the specification, illustrate the present embodiments and, together with the description, further serve to explain the principles of the present embodiments and to enable a person skilled in the relevant art(s) to make and use the present embodiments.

FIG. 1 illustrates a quantum dot enhancement film, according to an embodiment.

FIGS. 2A-2B illustrate an adhesive layer(s), according to an embodiment.

FIGS. 3A-3C illustrate a process of forming a quantum dot carrier, according to an embodiment.

FIGS. 4A-4C illustrate a process of disposing quantum dots within a material, according to an embodiment.

FIG. 5 illustrates the structure of a quantum dot, according to an embodiment.

FIG. 6 illustrates an example method, according to an embodiment.

FIG. 7 illustrates an example method, according to an embodiment.

FIG. 8 illustrates an example method, according to an embodiment.

The features and advantages of the present embodiments will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION OF THE INVENTION

Although specific configurations and arrangements may be discussed, it should be understood that this is done for illustrative purposes only. A person skilled in the pertinent art will recognize that other configurations and arrangements can be used without departing from the spirit and scope of the present invention. It will be apparent to a person skilled in the pertinent art that this invention can also be employed in a variety of other applications beyond those specifically mentioned herein.

It is noted that references in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

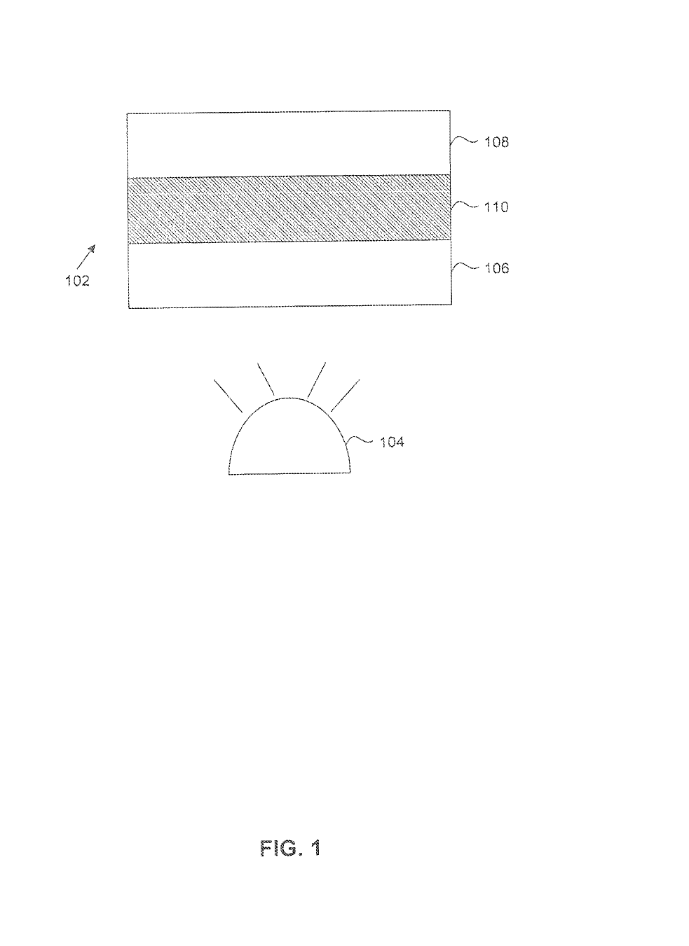

Quantum dots may be used in a variety of applications that benefit from having sharp, stable, and controllable emissions in the visible and infrared spectrum. One display technology involves the use of a quantum dot enhancement film where quantum dots are sandwiched between two protective layers. An example of a quantum dot enhancement film is illustrated in FIG. 1.

A quantum dot enhancement film (QDEF) 102 includes a bottom layer 106, a top layer 108, and a quantum dot layer 110 sandwiched between. An optical source 104 provides light from one side of the QDEF 102. Optical source 104 may be a variety of sources and may includes more than one light source. For example, optical source 104 may be one or more laser diodes or one or more light emitting diodes (LEDs). In one embodiment, optical source 104 includes one or more blue LEDs.

Bottom layer 106 and top layer 108 may be a variety of materials that are substantially transparent to the wavelengths being emitted by optical source 104 and the quantum dots trapped within quantum dot layer 110. For example, bottom layer 106 and top layer 108 may be glass or polyethylene terephthalate (PET). Bottom layer 106 and top layer 108 may also by polyester coated with aluminum oxide. Other polymers may be used as well that exhibit low oxygen permeability and low absorption for the wavelengths being emitted by the quantum dots trapped within quantum dot layer 110. It is not necessary that bottom layer 106 and top layer 108 be comprised of the same material.

Quantum dot layer 110 includes a plurality of quantum dots within an adhesive material. According to an embodiment, quantum dot layer 110 has a thickness around 100 micrometers (μm) and is used as a light down conversion layer. The adhesive material binds to both bottom layer 106 and top layer 108, holding the sandwich-like structure together.

In an embodiment, the plurality if quantum dots include sizes that emit in at least one of the green and red visible wavelength spectrums. The quantum dots are protected in quantum dot layer 110 from environmental effects and kept separated from one another to avoid quenching. The quantum dots may be spatially separated by enough distance such that quenching processes like excited state reactions, energy transfer, complex-formation and collisional quenching do not occur.

In one example, quantum dots are mixed within an amino silicone liquid and are emulsified into an epoxy resin that is coated to form quantum dot layer 110. However, such a process may reduce the quantum efficiency of certain types of quantum dots, such as indium phosphide (InP). Further details regarding the fabrication and operation of quantum dot enhancement films may be found in U.S. application Ser. No. 13/287,616, filed on Nov. 2, 2011, the disclosure of which is incorporated by reference herein in its entirety.

Embodiments herein relate to protecting the quantum dots within a porous solid material. Additionally, encapsulating the quantum dots within a porous structure allows for the use of quantum dots that may have poorer physical or processing properties. The porous structure protects the quantum dots from environmental effects and also from other materials that may quench the quantum dot emission. This can greatly increase the useable yield of epitaxial or colloidal quantum dots.

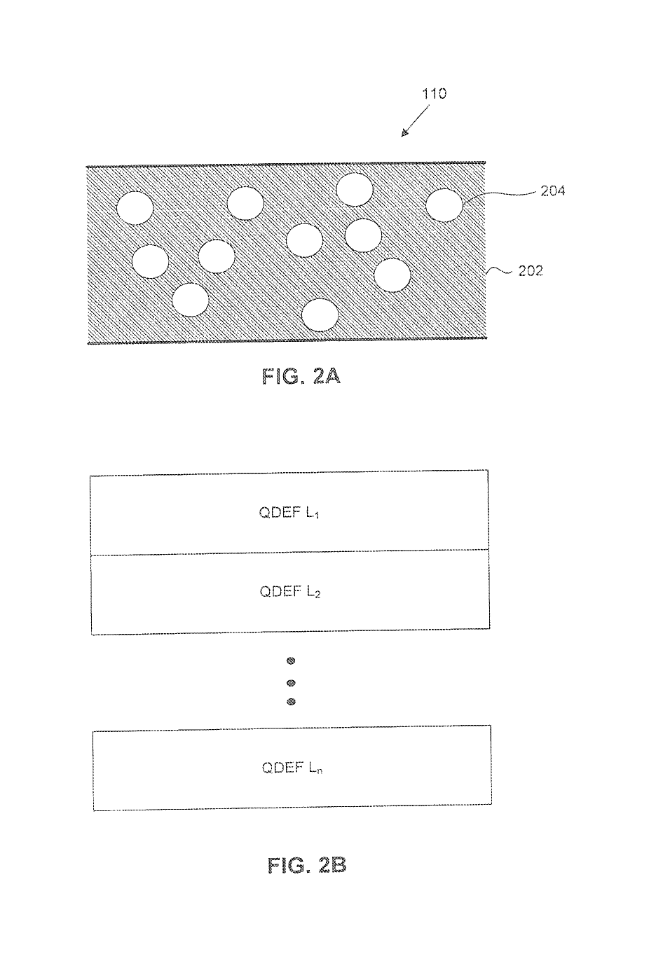

In one example, quantum dot carriers loaded with quantum dots are mixed with an adhesive and coated as quantum dot layer 110. FIG. 2A illustrates an example quantum dot layer 110 that includes adhesive material 202 and quantum dot carriers 204. Adhesive material 202 may be a variety of materials used to help bond the layers of the QDEF together. The QDEF may include any number of layers as illustrated in FIG. 2B. The layers may include alternating layers of PET and quantum dot layers. Adhesive material 202 may be chosen for its ability to protect quantum dot carriers 204 from oxygen and moisture exposure. Examples of adhesive material 202 include an epoxy resin, a curable polymer, acrylate-based adhesives, etc.

Quantum dot carriers 204 may each include a plurality of quantum dots, substantially protected from the environment by the carrier. In an embodiment, quantum dot carriers 204, include a porous material. The porous material may be a solid or semi-solid material depending on the environment. For example, depending on the temperature, the same porous material may be solid or semi-solid. The porous material may take on any shape, for example, a particle, fiber, or sheet. The porous particle may have a size less than about 100 μm. In one embodiment, the porous material is a silica particle about 40 μm in diameter. Other examples of porous particles include titanium oxide (TiO2), zeolites, molecular sieves, porous glass, sintered plastic, etc. As illustrated in FIG. 2, quantum dot carriers 204 may be suspended within adhesive material 202. Quantum dot carriers 204 may be packed at a varying density, which may be application dependent.

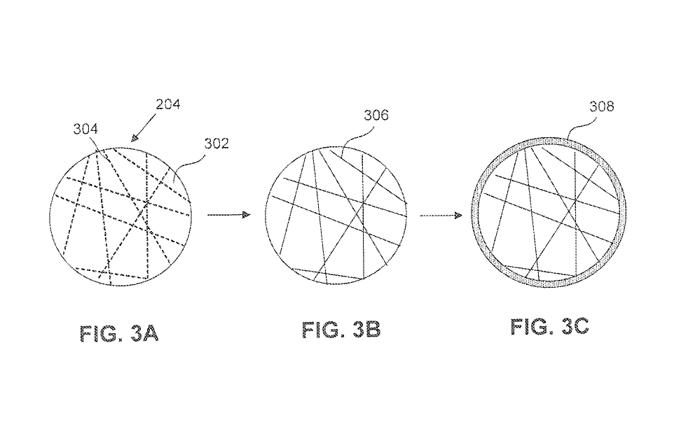

FIGS. 3A-3C illustrate an example process for loading quantum dots within quantum dot carrier 204. Quantum dot carrier 204 includes a porous material 302 having a plurality of pores 304. In one embodiment, quantum dot carrier 204 is a silica particle having pores that range between about 9 to 24 nm in diameter, or pores around 15 nm in diameter.

In one embodiment, quantum dot carrier 204 may be mixed with a curable monomer that includes a plurality of quantum dots. An example curable monomer is Lauryl methacrylate. Quantum dot carrier 204 absorbs the curable monomer solution within the plurality of pores 304. In one example, quantum dot carrier 204 is a silica particle having a diameter of around 40 μm and an average pore size of 15 nm that can absorb around 1.15 ml of solution within its pores. The absorbed curable monomer may contain a photoinitiator used to help crosslink and polymerize the monomer when exposed to ultraviolet (UV) radiation. By absorbing the monomer with the quantum dots mixed within it, a plurality of trapped quantum dots 306 are suspended within pores 304. The monomer material may help to disperse the quantum dots within porous material 302. In this way, the monomer material may be considered to be an example of a dispersive material. After absorbing the monomer, quantum dot carrier 204 may be exposed to UV light to polymerize the monomer within the pores of quantum dot carrier 204, thus trapping the suspended quantum dots within the pores. In an embodiment, an average of 60-70% of the pore volume within quantum dot carrier 204 is taken up with quantum dots following the absorption of the monomer mixed with the quantum dots.

Other procedures may be used to trap quantum dots within plurality of pores 304. For example, quantum dots may be mixed with a solvent and absorbed by the pores of quantum dot carrier 204. Afterwards, quantum dot carrier 204 may be heated to evaporate the solvent. The quantum dots may be adsorbed onto the inner walls of pores 304 via ligands attached on the outer surface of the quantum dots. The ligand material may help to disperse the quantum dots within plurality of pores 304. In this way, the ligands may be considered to be an example of a dispersive material.

After trapping the quantum dots within the pores 304, a sealing material 308 may optionally be applied to the outer surface of porous material 302. Sealing material 308 may fully encapsulate the quantum dots (and any absorbed polymer) within porous material 302. In an embodiment, sealing material 308 is substantially impermeable to at least one of oxygen and moisture. Examples of sealing material 308 include silicon dioxide, titanium oxide, or a polymer. Paralene may be used as the polymer sealing material. Numerous methods may be used for depositing sealing material 308. For example, sealing material 308 may be sputtered over the outer surface of porous material 302. In another example, sealing material 308 is deposited using atomic layer deposition (ALD).

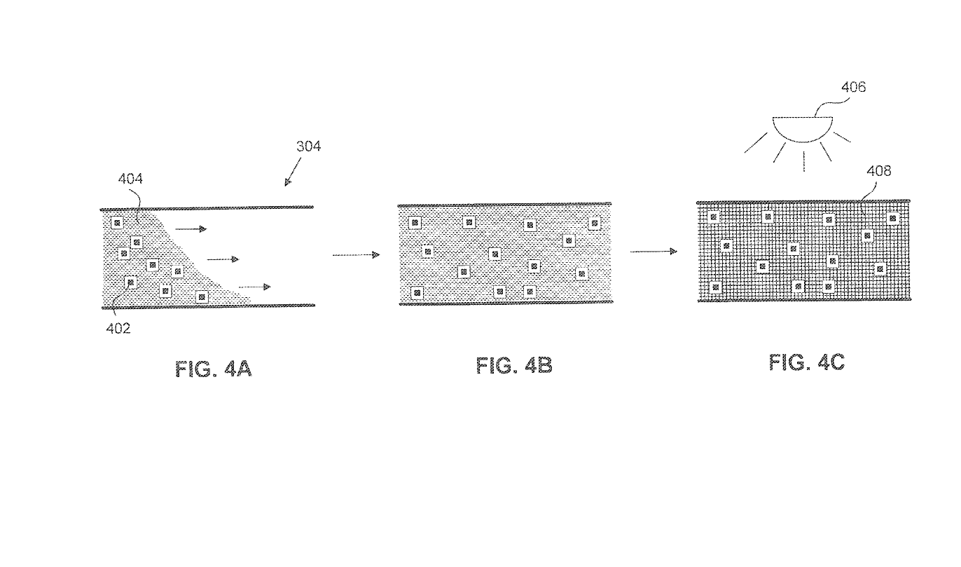

FIGS. 4A-4C illustrate an embodiment for filling a pore 304 with quantum dots 402. Quantum dots 402 may be suspended within a curable monomer 404. Curable monomer 404 may flow through pore 304 via capillary action or via an applied pressure. Once pore 304 is substantially filled with curable monomer 404, a UV light source 406 may be used to cure the monomer, according to an embodiment. The cured monomer polymerizes into polymer 408, immobilizing quantum dots 402 within pore 304.

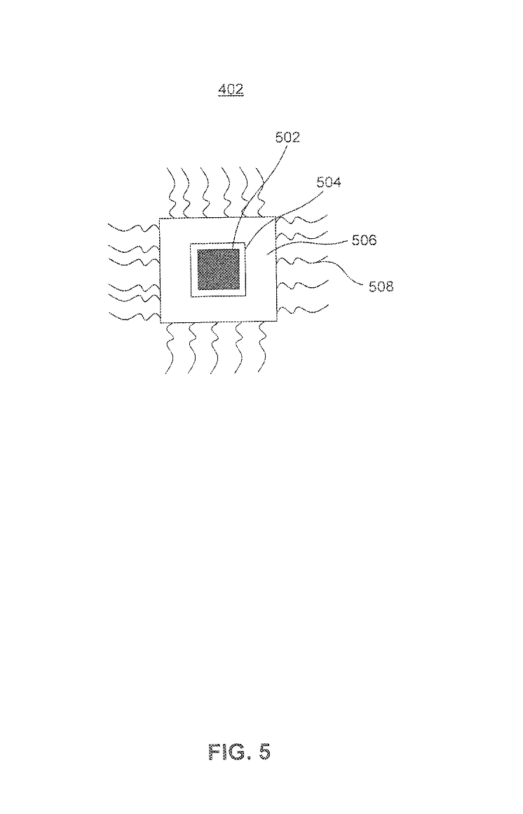

FIG. 5 illustrates an example of the core-shell structure of a quantum dot 402, according to an embodiment. Quantum dot 402 includes a core material 502, an optional buffer layer 504, a shell material 506, and a plurality of ligands 508. Core material 502 includes a semiconducting material that emits light upon absorption of higher energies. Examples of core material 502 include indium phosphide (InP), cadmium selenide (CdSe), zine sulfide (ZnS), lead sulfide (PbS), indium arsenide (InAs), indium gallium phosphide, (InGaP), and cadmium telluride (CdTe). Any other III-V, tertiary, or quaternary semiconductor structures that exhibit a direct band gap may be used as well. Of these materials. InP and CdSe are most often used, but InP is more desirable to implement over CdSe due to the toxicity of CdSe dust. CdSe may exhibit emissions having a full-width-half-max (FWHM) range of around 30 nm while InP may exhibit emissions having a FWHM range of around 40 nm.

Buffer layer 504 may surround core material 502. Buffer layer 504 may be zinc selenide sulfide (ZnSeS) and is typically very thin (e.g., on the order of 1 monolayer). Buffer layer 504 may be utilized to help increase the bandgap of core material 502 and improve the quantum efficiency.

Shell material 506 may be on the order of two monolayers thick and is typically, though not required, also a semiconducting material. The shells provide protection to core material 502. A commonly used shell material is zinc sulfide (ZnS), although other materials may be used as well without deviating from the scope or spirit of the invention. Shell material 506 may be formed via a colloidal process similar to that used to form core material 502.

Ligands 508 may be adsorbed or bound to an outer surface of quantum dot 402. Ligands 508 may be included to help separate (e.g. disperse) the quantum dots from one another. If the quantum dots are allowed to aggregate as they are being formed, the quantum efficiency drops and quenching of the optical emission occurs. Ligands 508 may also be used to impart certain properties to quantum dot 402, such as hydrophobicity, or to provide reaction sites for other compounds to bind.

A wide variety of ligands 508 exist that may be used with quantum dot 402. In an embodiment, ligands 508 from the aliphatic amine or aliphatic acid families are used. One example ligand is DDSA, which includes a hydrocarbon tail and exhibits good adhesion when used to adsorb quantum dot 402 onto the walls of a porous material.

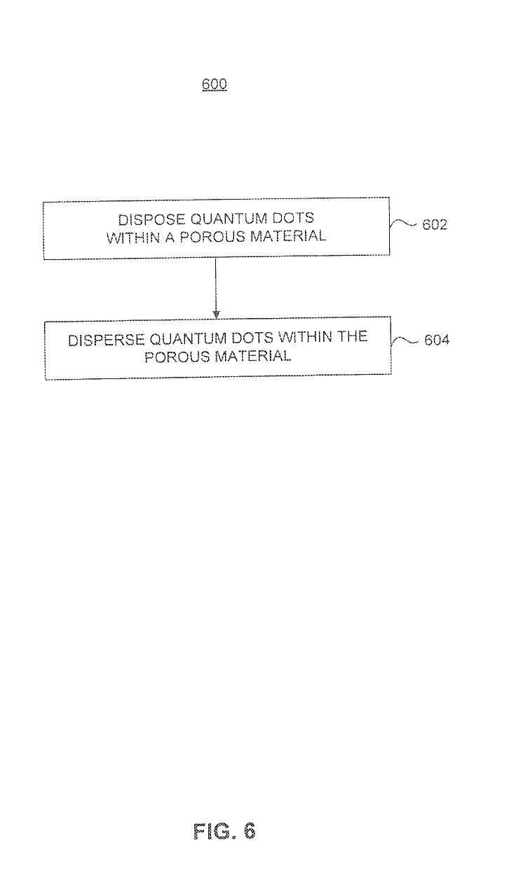

FIG. 6 illustrates an example method 600, according to an embodiment. Method 600 may be performed to fabricate a quantum dot carrier, such as quantum dot carrier 204. Method 600 is not intended to be exhaustive and other steps may be performed without deviating from the scope or spirit of the invention.

Method 600 begins with step 602 where quantum dots are disposed within a porous material, according to an embodiment. The quantum dots may be first mixed with a monomer or polymer solution before being adsorbed through the pores of the porous material. In another example, the quantum dots may be adsorbed onto the inner walls of the pores of the porous material.

In step 604, the quantum dots within the porous material are dispersed using a material disposed along with the quantum dots. For example, the quantum dots may include a plurality of ligands on their outer surface that helps to disperse and possibly protect the quantum dots. In another example, the quantum dots are mixed with a monomer material that disperses and protects the quantum dots. The monomer material with the quantum dots may be absorbed through the pores of the porous material.

Other fabrication steps may be performed as well. According to an embodiment, the outer surface of the porous material is encapsulated, sealed, or otherwise protected. The sealing may be performed by sputtering a material, such as silicon dioxide, over the outer surface of the porous material. In another example, the sealing is performed using ALD. A polymer may also be used to seal the outer surface of the porous material. The polymer may be a UV-curable polymer. In one embodiment, the polymer is paralene and may be deposited using chemical vapor deposition (CVD).

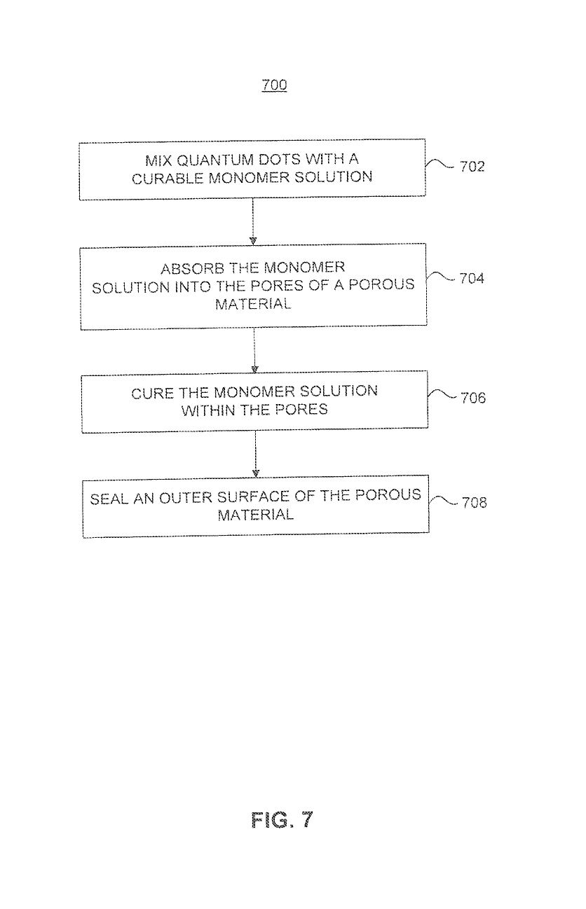

FIG. 7 illustrates a method 700, according to an embodiment. Method 700 may provide another procedure for fabricating a quantum dot carrier, such as quantum dot carrier 204. Method 700 is not intended to be exhaustive and other steps may be performed without deviating from the scope or spirit of the invention.

Method 700 begins with step 702 where quantum dots are mixed with a curable monomer solution, according to an embodiment. In another example, the quantum dots are mixed with a polymer that can be hardened via application of heat (or a cross-linking agent).

At step 704, the monomer mixed with the quantum dots is absorbed through the pores of a porous material, according to an embodiment. In one example, 60-70% of the empty pore space is filled with quantum dots following the absorption.

At step 706, the monomer mixed with the quantum dots is cured by exposing the monomer to UV light, according to an embodiment. A photoinitiator within the monomer solution reacts to the exposure of UV light and causes the monomers to bind together to form cross-linked polymers. The polymerization of the monomer solution within the pores immobilizes the quantum dots within the porous material.

At step 708, the outer surface of the porous material is sealed, according to an embodiment. The sealing may be performed by sputtering a material, such as silicon dioxide, over the outer surface of the porous material. In another example, the sealing is performed using ALD. A polymer may also be used to seal the outer surface of the porous material. The polymer may be a UV-curable polymer. In one embodiment, the polymer is paralene and may be deposited using chemical vapor deposition (CVD).

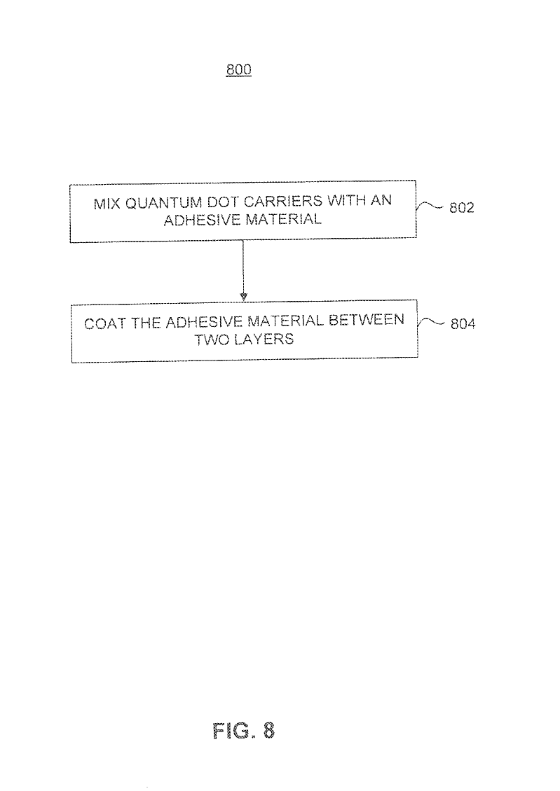

FIG. 8 illustrates a method 800, according to an embodiment. Method 800 may provide a procedure for fabricating a quantum dot enhancement film, such as QDEF 102. Method 800 is not intended to be exhaustive and other steps may be performed without deviating from the scope or spirit of the invention.

Method 800 begins with step 802 where the previously fabricated quantum dot carriers (including a porous material housing a plurality of quantum dots) are mixed with an adhesive material. The adhesive material may be a type of epoxy or an acrylate adhesive. In one example, the quantum dot carriers are mixed into the adhesive material at 20% loading.

At step 804, the adhesive material mixed with the quantum dot carriers is coated between two layers, according to an embodiment. The adhesive material acts as a bonding agent between the two layers. The two layers may be a variety of materials that are substantially transparent to the wavelengths being emitted by the quantum dots trapped within the quantum dot carriers. For example, the two layers may be glass or polyethylene terephthalate (PET). Optionally, another sealing material may be used around the edges of the bonded sandwich structure to further protect the quantum dots from any environmental contamination. A light source may be used with the bonded QDEF to excite the trapped quantum dots and cause them to emit wavelengths within the visible spectrum, depending on the size of the quantum dot. In one example, a blue light is used to cause the quantum dots to emit wavelengths in the range from 500 to 700 nm.

It should be understood that the embodiments discussed herein are not limited to use with QDEFs and can be used with a variety of display or imaging technologies. For example, embodiments of quantum dot carriers disclosed herein may be used as phosphor coatings or to create film products that no longer need to rely on expensive barrier layers to protect the quantum dots.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

What is claimed is:

1. A quantum dot carrier, comprising:
a porous material, wherein the porous material includes a plurality of pores;
a plurality of quantum dots within the plurality of pores of the porous material; and
a dispersing material within the plurality of pores and configured to disperse the plurality of quantum dots within the plurality of pores.

2. The quantum dot carrier of claim 1, wherein the plurality of pores have a pore size between 9 and 24 nanometers in diameter.

3. The quantum dot carrier of claim 1, wherein the porous material is a particle having a size less than 100 micrometers in diameter.

4. The quantum dot carrier of claim 3, wherein the particle is a silica particle, a titanium oxide particle, porous glass, or sintered plastic.

5. The quantum dot carrier of claim 1, wherein the porous material is a porous fiber.

6. The quantum dot carrier of claim 1, wherein the porous material is a porous film.

7. The quantum dot carrier of claim 1, wherein the plurality of quantum dots include quantum dots having a core material surrounded by a shell material.

8. The quantum dot carrier of claim 7, wherein the core material includes indium phosphide or cadmium selenide.

9. The quantum dot carrier of claim 8, wherein the shell material includes Zinc Sulfide.

10. The quantum dot carrier of claim 7, wherein the quantum dots include a buffer layer of zinc selenide sulfide (ZnSeS) between the core material and the shell material.

11. The quantum dot carrier of claim 1, wherein the dispersing material includes a plurality of ligands attached to the outer surface of the quantum dots.

12. The quantum dot carrier of claim 11, wherein the plurality of ligands include aliphatic amine groups.

13. The quantum dot carrier of claim 1, wherein the dispersing material comprises a curable monomer material absorbed through the plurality of pores of the porous material.

14. The quantum dot carrier of claim 1, further comprising:
a sealing material disposed on an outer surface of the porous material, and configured to be substantially impermeable to oxygen and moisture.

15. The quantum dot carrier of claim 14, wherein the sealing material is a polymer.

16. The quantum dot carrier of claim 14, wherein the sealing material comprises silicon dioxide.

17. A quantum dot enhancement film, comprising:
a first layer;
a second layer; and
an adhesive material disposed between the first layer and the second layer, the adhesive material comprising a plurality of quantum dot carriers wherein a quantum dot carrier of the plurality of quantum dot carriers comprises:
a porous material, wherein the porous material includes a plurality of pores,
a plurality of quantum dots within the plurality of pores of the porous material, and
a dispersing material within the plurality of pores and configured to disperse the plurality of quantum dots within the plurality of pores.

18. The quantum dot enhancement film of claim 17, wherein the first layer and the second layer are polyethylene terephthalate (PET) films.

19. The quantum dot enhancement film of claim 17, wherein the adhesive material is an epoxy resin.

20. The quantum dot enhancement film of claim 17, wherein the plurality of pores have a pore size between 9 and 24 nanometers in diameter.

21. The quantum dot enhancement film of claim 17, wherein the porous material is a silica particle.

22. The quantum dot enhancement film of claim 17, wherein the quantum dot carrier of the plurality of quantum dot carriers further comprises a sealing material disposed on an outer surface of the porous material, and configured to be substantially impermeable to at least one of oxygen and moisture

23. The quantum dot enhancement film of claim 17, wherein the dispersing material comprises a curable monomer material absorbed through the plurality of pores of the porous material.

24. The quantum dot enhancement film of claim 17, wherein the dispersing material comprises a plurality of ligands attached to the outer surface of the quantum dots.

25. A method comprising:
disposing a plurality of quantum dots within a porous material having a plurality of pores; and
dispersing the plurality of quantum dots within the porous material using a material disposed along with the quantum dots.

26. The method of claim 25, wherein the dispersing comprises:
mixing the plurality of quantum dots within a curable monomer solution; and
absorbing the curable monomer mixed with the plurality of quantum dots into the plurality of pores of the porous material.

27. The method of claim 25, further comprising:
mixing the porous material containing the plurality of quantum dots with an adhesive material; and
coating the adhesive material mixed with the porous material between two layers.

28. The method of claim 25, further comprising:
sealing an outer surface of the porous material with a sealing material, wherein the sealing material is substantially impermeable to at least one of oxygen and moisture.

29. The method of claim 28, wherein the sealing comprises performing an atomic layer deposition (ALD) process to coat the outer surface of the porous material with the sealing material.

30. The method of claim 25, wherein the disposing comprises disposing the plurality of quantum dots within a porous silica particle.
